(19) United States
(12) Patent Application Publication
(10) Pub. No.: US 2012/0199197 A1
(43) Pub. Date: Aug. 9, 2012

(54) SOLAR CELL

(76) Inventors: Wolfgang Volz, Ostfildern (DE); Tobias Mildenstein, Erfurt (DE); Gregor Kron, Stuttgart (DE)

(21) Appl. No.: 13/390,068

(22) PCT Filed: Aug. 3, 2010
(86) PCT No.: PCT/EP2010/061261

§ 371 Date: Apr. 24, 2012

(30) Foreign Application Priority Data
Aug. 10, 2009 (DE) 10 2009 028 393.5

(51) Int. Cl. H01L 31/024

(52) U.S. Cl. 136/259

(57) ABSTRACT

A solar cell having a flat cell substrate, which is transparent in the spectral region of visible light and in at least a partial range of the infrared spectral region, and having a cell structure situated on a surface of same, wherein, on the surface of the cell substrate carrying the cell structure, a bifunctional or multifunctional layer is applied which is transparent in the range of visible light, and has an infrared-reflecting and a contacting function.

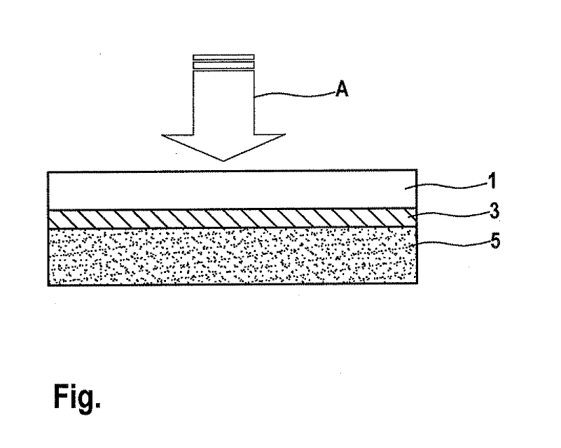

### FIELD OF THE INVENTION

The present invention relates to a solar cell having a flat cell substrate, which is transparent in the spectral region of visible light and in at least a partial range of the infrared spectral region, and having a cell structure situated on a surface of same.

### BACKGROUND INFORMATION

Photovoltaics is one of the most dynamic fields of energy technology, and is increasingly gaining economic importance. The development of variform configurations of solar cells and their technological refinement have greatly contributed to this in recent years. One substantial line of development relates to the provision of optimized carrier or substrate structures, which have advantageous optical and thermal properties within the meaning of high energy yield, and are technically easy and cost-effective to implement.

Glass having a transparent conductive layer, often a doped oxide layer (TCO), is generally used as a substrate for constructing various types of solar cells. This design is technologically simple and cost-effective to implement, and is able to fall back upon long-proven and easily available materials, and the design is largely transparent in the optical, as well as for extensive parts of the infrared (IR) spectral region.

For crystalline silicon, beginning at about 1100 nm, IR radiation does not have enough energy to generate electron-hole pairs, and thus to contribute to the photocurrent. For that reason, this type of radiation does not contribute positively to the effectiveness of the solar cell, but leads to additional heating, and thus to a worsening of the efficiency. For modules of crystalline Si solar cells, the efficiency reduction amounts to about 0.5%/° C., and, in the case of thin film cells, about 0.2-0.3%/° C. A conventional approach is to reflect the IR radiation, so that it does not penetrate into the solar cell, and is not able to lead to any additional heating in this way.

One configuration following this approach is described in different variants in European Patent No. EP 0 632 507 A2. An IR-reflecting system made of a plurality of protective layers suppresses reflections of a lower order, and thus reflects spectral bands which lie beyond the short-wave and long-wave borders of the wavelength range that the solar cell is able to use for the optoelectric conversion. The superstructures described are flexibly adjustable in their parameters, but are relatively costly in their implementation.

### SUMMARY

In accordance with the present invention, a solar cell is provided having a simplified construction and reduced manufacturing costs, whose construction nevertheless ensures sufficient screening from not usable portions of the incident sunlight.

In a departure from the design approach described in European Patent No. EP 0 632 507 A2, the present invention includes a simple substrate construction, whose manufacture requires only few steps. Furthermore, it includes implementing, for this purpose; various functions which the substrate construction has to implement, with regard to the actual cell construction, in a meaningful way, in as few layers as possible provided on the substrate. Only on the surface of the cell substrate carrying the cell structure, a bifunctional or multifunctional layer is applied which is transparent in the range of visible light, and has an infrared reflecting and a contacting function.

An advantage of the present invention is in the combination of two layers, the conductive front contact and the IR reflective layer, to form a bifunctional layer. This design results in an improved optical transmission of the usable solar radiation. In addition, the design simplifies the manufacturing and leads to a cost reduction, since only one coating process and one coating material are required. An additional advantage is a good thermal conductivity as well as the “interior position” of the conductive reflective layer. Because of this, the solar cell is able to dissipate heat without radiating, for otherwise the IR characteristic radiation would also be reflected, based on the cell temperature, and would thus lead to heating the cell. This would be the case if the IR reflective layer were positioned on the outside, that is, in the position of normal use of the side facing the sun, of the substrate. Because of the lower heat absorption based on the reflected IR radiation, the efficiency of the module improves, first of all. In addition, degradation effects, due to lower temperatures on the average, are minimized which, in turn, leads to an extended service life of the module.

One advantageous embodiment of minimizing the number of layers provides that the bifunctional or multifunctional layer has a high electrical conductivity. In particular, it has a sheet resistance of less than 15 Ω/□, in order to be able to be used without functional restrictions as the only front side contacting layer of the solar cell.

In another embodiment of the present invention, in a technologically proven and cost-effective manner, a glass substrate is used as the substrate. Specific glass compositions have long been established in the field of photovoltaics, and are usable in the embodiment of the present invention. With regard to the bifunctional or multifunctional coating that is important to the present invention, one may do without dyeing for filtering out IR radiation components by absorption, that is, one may perfectly well use “clear glass”. However, for use as the substrate material, basically high temperature-resistant, transparent plastics, quartz glasses and other proven transparent substrate materials may also be considered.

The object mentioned above is taken into account in a particular way if the bifunctional or multifunctional layer is provided as the only infrared-reflecting means and as the only front side contacting layer of the solar cell. However, this object may also be achieved, to a certain extent, if the layer exclusively fulfills only one of these two functions, while, for the complete fulfillment of the respectively remaining function, one more layer is provided.

Within the meaning of the aforementioned advantage of an improved optical transmission and a lower absorption of the sunlight usable in the cell, the bifunctional or multifunctional layer has an absorption coefficient, in the spectral region of visible light, below a provided threshold value, in particular below 20%. Depending on the power requirements and the physical parameters of the actual solar cell, another value may also be specified, however.

In one preferred embodiment of the present invention, within the meaning of as efficient as possible a turning away of the harmful IR radiation, it is provided that the bifunctional or multi-functional layer, in a partial range of the infrared spectral region, has a reflection coefficient above a predetermined threshold value, particularly at 1100 nm and more, above 50%. Even compared to these values, modifications are possible as a function of the specific cell structure and the overall design, and perhaps meaningful.

The complex functionality of the substrate coating provided may be achieved in an expedient and reliable manner if the bifunctional or multi-functional layer has metal particles, particularly silver particles having an average grain size in the nanometer or micrometer range, especially of 100 nm or less. Besides silver, other metals are also suitable, thus, for example, as a function of the remaining properties of the module design, gold or copper or alloys of the metals named. One may also deviate from the upper limit of the preferred grain size named, and it may also be advantageous to use intercalation material having a predetermined grain size distribution.

### BRIEF DESCRIPTION OF THE DRAWING

The FIGURE shows schematically a construction of an example solar cell according to the present invention.

### DETAILED DESCRIPTION OF EXAMPLE EMBODIMENTS

The FIGURE shows schematically as a cross-sectional representation the construction of a solar cell 1 according to the present invention, having a glass substrate 1, a bifunctional (electrically conductive and IR reflecting) layer 3 and a solar cell structure 5, exposed to sunlight radiation in the state of use in this sequence, symbolized by arrow A. Bifunctional layer 3, made up, for instance, of Ag nanoparticles, is in thermal contact to the glass, as well as to the actual solar cell, and has a good heat conductivity.

The incident IR component of the solar radiation is reflected by the reflection layer, and in this way, it does not contribute to the heating of the solar cell. In addition, the layer takes over the function of the front contact, no additional TCO or comparable layer becoming necessary, which would lessen the optical transmission and thus decrease the efficiency of the solar cell. Based on the good conductivity, the heat of the solar cell is conducted on to the substrate by the reflection layer, and the substrate radiates energy corresponding to its emissivity and temperature.

1-9. (canceled)

10. A solar cell, comprising:
a flat cell substrate which is transparent in a spectral region of visible light and in at least a partial range of an infrared spectral region;
a cell structure situated on a surface of the cell substrate; and
one of a bifunctional or multifunctional layer applied to the surface of the cell substrate carrying the cell structure, the layer being transparent in a range of visible light, and having an infrared-reflecting and a contacting function.

11. The solar cell as recited in claim 10, wherein the one of the bifunctional or multifunctional layer is electrically conductive, having a sheet resistance below a predetermined threshold value, the predetermined threshold value being below 15 Ω/□.

12. The solar cell as recited in claim 10, wherein the substrate one of is a glass substrate or has a glass substrate.

13. The solar cell as recited in claim 10, wherein the one of the bifunctional or multifunctional layer is provided as the only infrared-reflecting element of the solar cell.

14. The solar cell as recited in claim 10, wherein one of the bifunctional or multifunctional layer is provided as the only front side contacting layer of the solar cell.

15. The solar cell as recited in claim 10, wherein the one of the bifunctional or multifunctional layer is thermally conductive, and is in thermally conductive contact to at least one of the cell substrate and to the cell structure.

16. The solar cell as recited in claim 10, wherein the one of the bifunctional or multifunctional layer has an absorption coefficient, in the spectral range of visible light, that is below a particular threshold value, the threshold value being below 20%.

17. The solar cell as recited in claim 10, wherein the one of the bifunctional or multifunctional layer has a reflection coefficient in a partial range of the infrared spectral region that is above a predetermined threshold value.

18. The solar cell as recited in claim 10, wherein the threshold value is at least 1100 nm.

19. The solar cell as recited in claim 10, wherein the one of the bifunctional or multifunctional layer has silver particles having an average grain size less than 100 nm.
